(19) United States
(12) Patent Application Publication
(10) Pub. No.: US 2002/0069816 A1
(43) Pub. Date: Jun. 13, 2002

(54) Methods of fabricating gallium nitride layers on textured silicon substrates, and gallium nitride semiconductor structures fabricated thereby

(76) Inventors: Thomas Gehrke, Apex, NC (US); Kevin J. Linthicum, Angier, NC (US); Robert F. Davis, Raleigh, NC (US)

Correspondence Address: MOORE & VAN ALLEN, PLLC, 2200 W MAIN STREET, SUITE 800, DURHAM, NC, 27705, US

(21) Appl. No.: 09/736,569

(22) Filed: Dec. 13, 2000

Related U.S. Application Data
(60) Provisional application No. 60/170,433, filed on Dec. 13, 1999.

(51) Int. Cl. C30B 23/00; C30B 25/00; C30B 28/12; C30B 28/14

(52) U.S. Cl. 117/84

(57) ABSTRACT

A gallium nitride semiconductor layer is fabricated by exposing (111) crystallographic planes in a face of a (100) silicon substrate, and growing hexagonal gallium nitride on the (111) crystallographic planes that are exposed. Thus, a (100) silicon substrate, which is widely used for fabricating conventional microelectronic devices such as bipolar and field effect transistors, may be used to fabricate gallium nitride semiconductor layers thereon. The (111) crystallographic planes may be exposed in the face of the (100) silicon substrate by wet-etching the face of the (100) silicon substrate. More specifically, the face of the (100) silicon substrate may be dipped in KOH for a short period of time, such as about ten seconds or less, to expose the (111) crystallographic planes therein. The face of the (100) silicon substrate may be unmasked when dipped in KOH, to thereby expose randomly spaced apart (111) crystallographic planes in the face of the (100) silicon substrate. Alternatively, the face of the (100) silicon substrate may be masked prior to dipping in the KOH, to thereby expose a periodic or nonrandom pattern of (111) crystallographic planes therein.

### CROSS-REFERENCE TO RELATED APPLICATION

This application claims the benefit of provisional Application Serial No. 60/170,433, filed Dec. 13, 1999, entitled Growth of GaN Thin Films on Silicon (001) Substrates, and Gallium Nitride Semiconductor Structures Fabricated Thereby to the present inventors.

### FEDERALLY SPONSORED RESEARCH

This invention was made with Government support under Office of Naval Research Contract No. N00014-98-1-0654. The Government may have certain rights to this invention.

### FIELD OF THE INVENTION

This invention relates to microelectronic devices and fabrication methods, and more particularly to gallium nitride semiconductor devices and fabrication methods therefor.

### BACKGROUND OF THE INVENTION

Gallium nitride is being widely investigated for microelectronic devices such as transistors and field emitters; and optoelectronic devices, such as lasers and light emitting diodes. It will be understood that, as used herein, gallium nitride also includes alloys of gallium nitride such as aluminum gallium nitride, indium gallium nitride and aluminum indium gallium nitride.

A major problem in fabricating gallium nitride-based microelectronic devices is the fabrication of gallium nitride semiconductor layers having low defect densities. It is known that one contributor to defect density is the substrate on which the gallium nitride layer is grown. Accordingly, although gallium nitride layers have been grown on sapphire substrates, it is known to reduce defect density by growing gallium nitride layers on aluminum nitride buffer layers which are themselves formed on silicon carbide substrates. Notwithstanding these advances, continued reduction in defect density is desirable.

It also is known to produce low defect density gallium nitride layers by forming a mask on a layer of gallium nitride, the mask including at least one opening that exposes the underlying layer of gallium nitride, and laterally growing the underlying layer of gallium nitride through the at least one opening and onto the mask. This technique often is referred to as “Epitaxial Lateral Overgrowth” (ELO). The layer of gallium nitride may be laterally grown until the gallium nitride coalesces on the mask to form a single layer on the mask. In order to form a continuous layer of gallium nitride with relatively low defect density, a second mask may be formed on the laterally overgrown gallium nitride layer, that includes at least one opening that is offset from the underlying mask. ELO then again is performed through the openings in the second mask to thereby overgrow a second low defect density continuous gallium nitride layer. Microelectronic devices then may be formed in this second overgrown layer. ELO of gallium nitride is described, for example, in the publications entitled Lateral Epitaxy of Low Defect Density GaN Layers Via Organometallic Vapor Phase Epitaxy to Nam et al., Appl. Phys. Lett. Vol. 71, No. 18, Nov. 3, 1997, pp. 2638-2640; and Dislocation Density Reduction Via Lateral Epitaxy in Selectively Grown GaN Structures to Zheleva et al, Appl. Phys. Lett., Vol. 71, No. 17, Oct. 27, 1997, pp. 2472-2474, the disclosures of which are hereby incorporated herein by reference.

It also is known to produce a layer of gallium nitride with low defect density by forming at least one trench or post in an underlying layer of gallium nitride to define at least one sidewall therein. A layer of gallium nitride is then laterally grown from the at least one sidewall. Lateral growth preferably takes place until the laterally grown layers coalesce within the trenches. Lateral growth also preferably continues until the gallium nitride layer that is grown from the sidewalls laterally overgrows onto the tops of the posts. In order to facilitate lateral growth and produce nucleation of gallium nitride and growth in the vertical direction, the top of the posts and/or the trench floors may be masked. Lateral growth from the sidewalls of trenches and/or posts also is referred to as “pendeoepitaxy” and is described, for example, in publications entitled Pendeo-Epitaxy: A New Approach for Lateral Growth of Gallium Nitride Films by Zheleva et al., Journal of Electronic Materials, Vol. 28, No. 4, February 1999, pp. L5-L8; and Pendeoepitaxy of Gallium Nitride Thin Films by Linthicum et al., Applied Physics Letters, Vol. 75, No. 2, July 1999, pp. 196-198, the disclosures of which are hereby incorporated herein by reference.

ELO and pendeoepitaxy can provide relatively large, low defect gallium nitride layers for microelectronic applications. However, a major concern that may limit the mass production of gallium nitride devices is the growth of the gallium nitride layers on a silicon carbide substrate. Notwithstanding silicon carbide's increasing commercial importance, silicon carbide substrates still may be relatively expensive compared to conventional silicon substrates. Moreover, silicon carbide substrates may be smaller than silicon substrates, which can reduce the number of devices that can be formed on a wafer. Finally, although large investments are being made in silicon carbide processing equipment, even larger investments already may have been made in conventional silicon substrate processing equipment. Accordingly, the use of an underlying silicon carbide substrate for fabricating gallium nitride microelectronic structures may adversely impact the cost and/or availability of gallium nitride devices.

Methods of fabricating gallium nitride layers on silicon substrates are described in published PCT Application WO 00/31783 to Linthicum et al., entitled Fabrication of Gallium Nitride Layers on Silicon, the disclosure of which is hereby incorporated herein by reference. As described in this published PCT application, a gallium nitride microelectronic layer is fabricated by converting a surface of a (111) silicon layer to 3C-silicon carbide. A layer of 3C-silicon carbide is then epitaxially grown on the converted surface of the (111) silicon layer. A layer of 2H-gallium nitride then is grown on the epitaxially grown layer of 3C-silicon carbide. The layer of 2H-gallium nitride then is laterally grown to produce the gallium nitride microelectronic layer. In one embodiment, the silicon layer is a (111) silicon substrate, the surface of which is converted to 3C-silicon carbide. In another embodiment, the (111) silicon layer is part of a Separation by IMplanted OXygen (SIMOX) silicon substrate which includes a layer of implanted oxygen that defines the (111) layer on the (111) silicon substrate. In yet another embodiment, the (111) silicon layer is a portion of a Silicon-On-Insulator (SOI) substrate in which a (111) silicon layer is bonded to a substrate. Lateral growth of the layer of 2H-gallium nitride may be performed by Epitaxial Lateral Overgrowth (ELO) wherein a mask is formed on the layer of 2H-gallium nitride. See the Abstract of published PCT Application WO 00/31783.

### SUMMARY OF THE INVENTION

Embodiments of the present invention fabricate a gallium nitride semiconductor layer by exposing (111 ) crystallographic planes in a face of a (100) silicon substrate, and growing hexagonal gallium nitride on the (111) crystallographic planes that are exposed. Thus, a (100) silicon substrate, which is widely used for fabricating conventional microelectronic devices such as bipolar and field effect transistors, may be used to fabricate gallium nitride semiconductor layers thereon. Integration of conventional microelectronic devices in a (100) silicon substrate and gallium nitride-based optoelectronic devices in a gallium nitride layer on the (100) silicon substrate thereby may be provided.

According to embodiments of the invention, the (111) crystallographic planes are exposed in the face of the (100) silicon substrate by wet-etching the face of the (100) silicon substrate. More specifically, the face of the (100) silicon substrate may be dipped in KOH for a short period of time, such as about ten seconds or less, to expose the (111) crystallographic planes therein. The face of the (100) silicon substrate may be unmasked when dipped in KOH, to thereby expose randomly spaced apart (111) crystallographic planes in the face of the (100) silicon substrate. Alternatively, the face of the (100) silicon substrate may be masked prior to dipping in the KOH, to thereby expose a periodic pattern of (111) crystallographic planes therein.

In other embodiments, prior to growing hexagonal gallium nitride on the (111) crystallographic planes that are exposed, a buffer layer comprising aluminum nitride is formed on the (111) crystallographic planes that are exposed. The hexagonal gallium nitride then is grown on the buffer layer. In yet other embodiments, a multi-layer buffer layer may be provided that includes a first layer comprising silicon carbide on the exposed (111) planes of the silicon substrate, and a second layer comprising aluminum nitride on the first layer comprising silicon carbide, opposite the exposed (111) planes. The silicon carbide layer may be formed by converting the exposed (111) planes to 3C-silicon carbide, for example by chemically reacting the surface of the (111) silicon planes with a carbon-containing precursor, such as ethylene.

In other embodiments of the present invention, the hexagonal gallium nitride is grown on the (111) crystallographic planes until the hexagonal gallium nitride coalesces to form a continuous hexagonal gallium nitride layer. At least one microelectronic device, including an optoelectronic device such as a laser or light emitting diode, is formed in the hexagonal gallium nitride layer, preferably in the continuous hexagonal gallium nitride layer.

In some embodiments of the present invention, the (100) silicon substrate is a bulk (100) silicon substrate. In other embodiments, the (100) silicon substrate is a (100) silicon layer on a silicon substrate, such as a Silicon-On-Insulator (SOI) substrate, including a Separation by IMplanted OXygen (SIMOX) silicon substrate. In still other embodiments of the invention, the (100) silicon substrate is a (100) silicon layer on a non-silicon substrate, such as a silicon carbide, sapphire or other conventional substrate.

Gallium nitride semiconductor structures according to embodiments of the invention include a (100) silicon substrate including a textured or roughened face and a hexagonal gallium nitride layer on the textured face. The textured face preferably exposes (111) crystallographic planes in the face. The crystallographic planes may be regularly spaced apart and/or randomly spaced apart. A buffer layer comprising gallium nitride and/or silicon carbide layers may be provided. A continuous or discontinuous gallium nitride layer may be provided, and one or more microelectronic devices including optoelectronic devices may be provided therein. The (100) silicon substrate may be a bulk substrate or a (100) silicon layer on a silicon or non-silicon substrate.

### BRIEF DESCRIPTION OF THE DRAWINGS

FIGS. 1A-1D are cross-sectional views of first gallium nitride structures according to embodiments of the present invention, during intermediate fabrication steps according to embodiments of the present invention.

FIG. 1B′ is an enlarged view of a portion of FIG. 1B.

FIG. 2 is a top view of structures of FIG. 1B.

FIGS. 3A-3D are cross-sectional views of gallium nitride microelectronic structures according to other embodiments of the present invention, during intermediate fabrication steps according to other embodiments of the invention.

FIG. 4 is a top view of structures of FIG. 3A.

FIGS. 5A-5E are perspective views of gallium nitride microelectronic structures according to embodiments of the invention, during intermediate fabrication steps according to embodiments of the present invention.

FIG. 6 is a X-ray diffraction graph of gallium nitride microelectronic layers according to embodiments of the present invention.

### DETAILED DESCRIPTION OF PREFERRED EMBODIMENTS

The present invention now will be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout. It will be understood that when an element such as a layer, region or substrate is referred to as being “on” another element, it can be directly on the other element or intervening elements may also be present. In contrast, when an element is referred to as being “directly on” another element, there are no intervening elements present. Moreover, each embodiment described and illustrated herein includes its complementary conductivity type embodiment as well. Finally, it should be noted that, in some alternative embodiments of the present invention, the operations shown in the figures may occur out of the order noted in the figures. For example, operations of two figures shown in succession may in fact be performed substantially concurrently or the operations of successive figures may sometimes be performed in the reverse order.

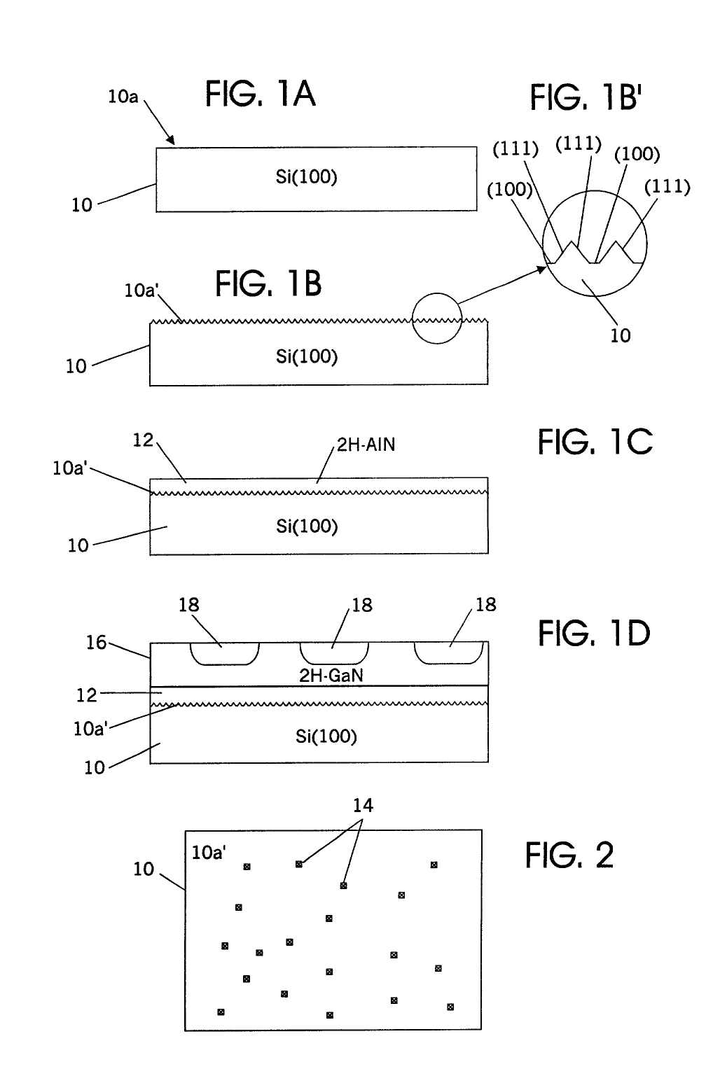

Referring now to FIGS. 1A-1D, 1B′ and 2, first embodiments of methods of fabricating gallium nitride microelectronic structures and first embodiments of microelectronic structures formed thereby, according to embodiments of the present invention, are illustrated. As shown in FIG. 1A, a bulk silicon (100) substrate 10 is provided. As is well known to those having skill in the art, bulk silicon (100) wafers are widely used for fabricating microelectronic devices, such as field effect transistors including Complementary Metal Oxide Semiconductor (CMOS) devices, and therefore are widely available. Embodiments of the present invention can allow microelectronic devices, such as optoelectronic devices including light emitting diodes and lasers, to be fabricated in a gallium nitride layer that itself is fabricated on a conventional silicon (100) substrate 10. It also will be understood by those having skill in the art that the substrate 10 also may be a (100) silicon layer on a silicon or non-silicon substrate. When using a silicon substrate, the (100) silicon layer may be part of a Separation by IMplanted OXygen (SIMOX) silicon substrate, which includes a layer of implanted oxygen that defines the (100) layer on a (100) silicon substrate. In yet another embodiment, the (100) silicon layer is a portion of a Silicon-on-Insulator (SOI) substrate in which a (100) silicon layer is bonded to a substrate which can be a conventional silicon substrate, another semiconductor substrate or a non-semiconductor substrate, such as glass substrates. Accordingly, the present invention can use conventional bulk silicon (100) substrates, SIMOX and SOI substrates as a base or platform for fabricating a gallium nitride microelectronic layer. By using conventional silicon technology, low-cost and/or large area silicon substrates may be used, and conventional silicon wafer processing systems also may be used. Moreover, gallium nitride-based devices may be integrated on a single substrate with conventional silicon devices, such as CMOS devices.

Referring now to FIG. 1B, a face 10a of the silicon (100) substrate is textured or roughened. The substrate may be textured by wet-etching the face 10a. More particularly, wet-etching is performed in potassium hydroxide (KOH) for a period of time that is preferably between about 5 seconds and about 30 seconds, and more preferably about ten seconds. The KOH may be a 45% solution by volume of KOH in water. Other anisotropic wet etching solutions for (100) silicon substrates, such as potassium hydroxide/isopropyl alcohol, CsOH, TMAH and ethylenediamine/pyrocetechol/water may be used. See, for example, http://www.eecs.uic.edu/˜peter/eecs449/lectures/anisotropicSietch.html.

As shown schematically in FIG. 1B, the textured face 10a′ has surface texturing or roughness compared to the generally polished face 10a of the silicon (100) substrate. The texturing or roughness may create features on the substrate that are on the order of 0.2 μm in size. Stated in terms of surface roughness, a surface roughness of about 20 nm may be provided. This contrasts with ELO or pendeoepitaxial growth, which may create mask opening or trench width features that are on the order of 4 μm in size.

Without wishing to be bound by any theory of operation, it is theorized that the dipping in KOH for a short period of time anisotropically etches the face 10a of the silicon substrate 10, to thereby expose (111) crystallographic planes in the face, and thereby produce the textured face 10a′. As shown in FIG. 1B′, the (111) planes are selectively exposed by the anisotropic etching. More specifically, as is well known to those having skill in the art, since silicon has a cubic structure with (100) planes at cubic faces, the anisotropic etch can expose multiple (111) planes.

FIG. 2 is a top view of the textured face 10a′ of the substrate 10. As shown in FIG. 2, randomly distributed exposed (111) planes 14 may be provided which can act as seed layers for later growth of hexagonal gallium nitride. As was described above, the exposed (111) planes 14 may be on the order of 0.2 μm in size, and may have a percentage of (111) faced surface to total surface area that preferably exceeds 50%, more preferably exceeds 75% and most preferably exceeds 90%.

Referring now to FIG. 1C, a buffer layer 12 comprising aluminum nitride then is formed on the textured face 10a′ of the silicon (100) substrate 10. The aluminum nitride buffer layer 12 preferably comprises 2H-aluminum nitride, may be about 0.01 μm thick and may be formed using conventional techniques, such as metallorganic vapor phase epitaxy, for example as described in detail in the abovecited PCT publication WO 00/31783. The fabrication of an aluminum nitride buffer layer 12 is well known to those having skill in the art, and need not be described further herein.

Then, referring to FIG. 1D, a layer comprising 2H-gallium nitride 16 is epitaxially grown on the aluminum nitride buffer layer 12. The gallium nitride layer 16 may be fabricated, for example, at 1000-1100° C. and at 45 Torr using the precursors TEG at 13-39 μmol/min and NH₃ at 1500 sccm in combination with a 3000 sccm H₂ diluent, as was described extensively in the above-cited PCT publication WO 00/31783. The epitaxial growth of 2H-gallium nitride on a 2H-aluminum nitride buffer layer is well known to those having skill in the art and need not be described in detail herein.

As shown in FIG. 1D, the gallium nitride layer 16 preferably coalesces to form a continuous hexagonal gallium nitride layer. Moreover, as shown in FIG. 1D, at least one microelectronic device 18, which may be an optoelectronic device such as a light emitting diode and/or a laser, is formed in the gallium nitride layer 16. If additional microelectronic devices are formed in the (100) silicon substrate 10, prior to, during and/or after formation of the microelectronic devices 18, integrated heterostructures that include both gallium nitride and silicon-based microelectronic devices may be provided, using conventional (100) silicon substrates.

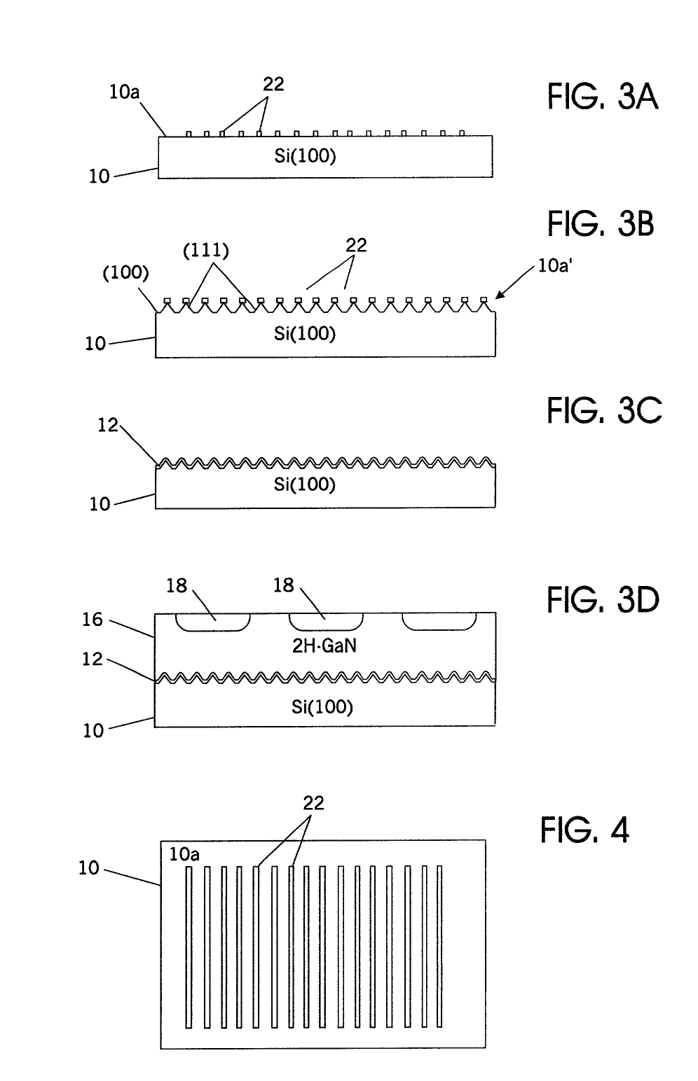

In FIG. 1B, dipping of an unmasked (100) silicon substrate 10 in KOH was performed to form a randomly textured face 10a′. In embodiments of FIGS. 3A-3D and 4, a mask is used, to thereby expose periodic or nonrandom (111) crystallographic planes in the (100) face 10a.

More specifically, as shown in FIG. 3A, a face 10a of a (100) silicon substrate 10 is masked with a patterned mask 22, for example using conventional masking techniques. As shown in the top view of FIG. 4, the mask 22 may be a series of equally spaced apart stripes, wherein the stripes may be of width between about 0.2 μm and about 1.0 μm, and have a spacing therebetween of between about 0.5 μm and about 1.0 μm. Preferably, the masks are 0.2 μm wide and have a spacing of 0.5 μm therebetween. Nonuniform spacings and/or widths also may be used.

Then, referring to FIG. 3B, the masked substrate of FIG. 3A is dipped in a solution of KOH and/or other anisotropic etchants for periods of time that were described above, to thereby expose the (111) planes in the (100) face, and thereby provide a textured face 10a′. It will be understood that the width and spacing of the mask 22 preferably is selected to expose a relatively large number of (111) planes, while leaving a relatively small amount of the (100) plane exposed. Preferably, the number of (111) planes that are exposed is maximized, and the amount of the (100) plane that remains is minimized and, more preferably, eliminated. After texturing, the mask 22 may be removed. Alternatively, it may remain.

FIG. 3C illustrates the formation of a 2H-aluminum nitride layer 12, similar to that of FIG. 1C, and will not be described in further detail. FIG. 3D illustrates the growth of a 2H-gallium nitride layer 16 and the formation of microelectronic devices 18 therein, as was described in connection with FIG. 1D, and will not be described again herein.

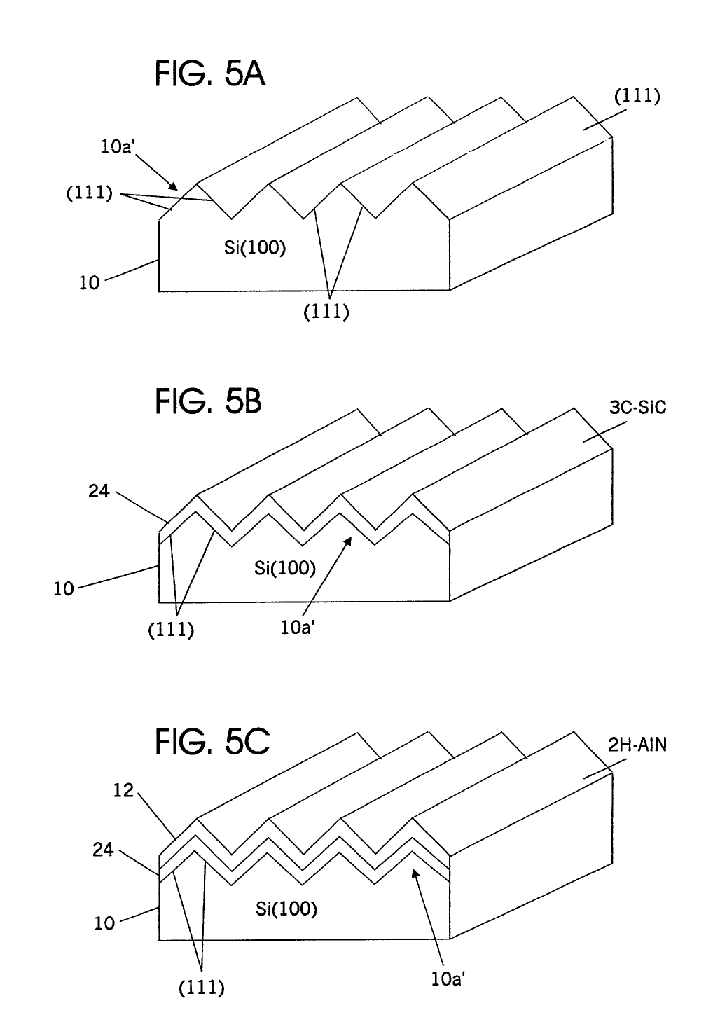

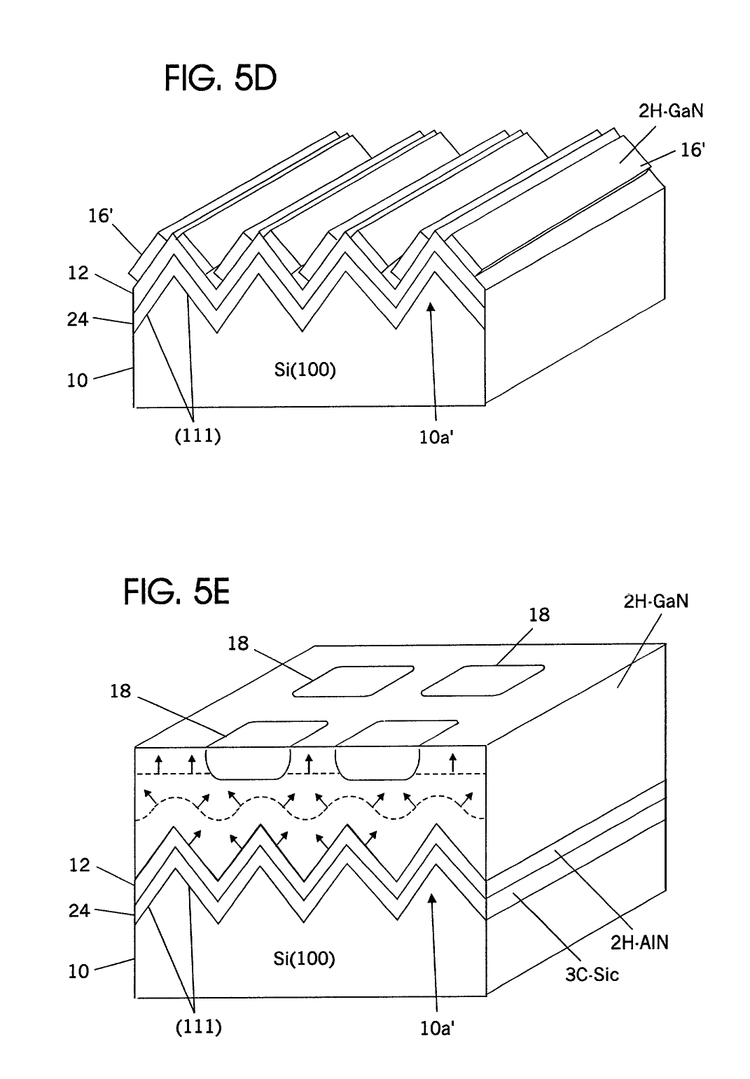

FIGS. 5A-5E are perspective views of other embodiments of the present invention. FIG. 5A illustrates formation of a (100) silicon substrate 10 having a textured face 10a′ that may be random and/or nonrandom, as was described in connection with FIGS. 1B and 3B, and will not be described again herein.

Referring to FIG. 5B, the first buffer layer 24 comprising 3C-silicon carbide is formed on the textured face 10a′. The 3C-silicon carbide buffer layer 24 may be fabricated by converting the exposed (111) silicon planes to 3C-silicon carbide, for example, by exposure to one or more carbon-containing sources. More specifically, a converted layer of 3C-silicon carbide may be formed by heating the substrate using ethylene at about 925° C. for about fifteen minutes at a pressure of about 5×10⁻⁵ Torr, as described in detail in the above-cited PCT Publication WO 00/31783, and in a publication entitled Pendeo-epitaxial Growth of GaN on Silicon to Gehrke et al., Journal of Electronic Materials, Vol. 29, No. 3, 2000, the disclosure of which is hereby incorporated herein by reference. It also will be understood that other techniques of forming a layer of 3C-silicon carbide 24 on exposed (111) planes of a (100) silicon substrate 10 may be used. It also will be understood that an additional silicon carbide layer may be grown on the converted surface and the silicon carbide layer may be thinned, as described in the above-cited PCT Publication WO 00/31783.

Referring now to FIG. 5C, a second buffer layer comprising 2H-aluminum nitride 12 then is formed on the layer 24 comprising 3C-silicon carbide using, for example, techniques that were described above in connection with FIGS. 1C and 3C. It also will be understood that a layer 24 comprising silicon carbide also may be included in embodiments of FIGS. 1C-1D and 3C-3D.

Then, referring to FIG. 5D, a layer 16′ of 2H-gallium nitride is grown, preferably selectively grown, on the exposed (111) planes. Finally, as shown in FIG. 5E, the layer 16′ of 2H-gallium nitride continues to grow and coalesces to form a continuous gallium nitride semiconductor layer 16. The dashed lines and arrows within layer 16 of FIG. 5E illustrate the coalescence of the gallium nitride growth fronts, to form a common growth front that is generally perpendicular to the original face of the (100) silicon substrate 10, to form a continuous and smooth gallium nitride semiconductor layer 16. The dashed lines indicate how the texture due to the etching can even out, while the gallium nitride growth continues to form one common growth front. Finally, microelectronic devices 18 may be formed, as was described in connection with FIGS. 1D and 3D.

Accordingly, single crystal wurtzitic α (2H) gallium nitride semiconductor layers 16 may be grown on single crystal silicon (100) substrate wafers 100, or SOI substrate wafers including SIMOX wafers. Silicon (100) presently is the most widely used substrate for integrated silicon-based devices, such as CMOS devices. Accordingly, embodiments of the present invention can allow gallium nitride and silicon-based devices to be integrated in one chip that is grown on a silicon substrate. Embodiments of the present invention can use an anisotropic etch to selectively expose (111) planes in a (100) face of a (100) silicon substrate. The anisotropic wetetching process of the face of the silicon (100) wafer can be employed to expose silicon (111) planes due to their slow etching rate. Gallium nitride then may grown on the exposed (111) planes using a 3C-silicon carbide and/or 2H-aluminum nitride buffer layers, since the cubic unit cell of the substrate and the hexagonal unit cell of the buffer layer(s) can match up.

During the growth of the gallium nitride layer 16, gallium nitride may start growing in different directions, but eventually coalesces and forms a continuous and smooth gallium nitride layer that can be used for device fabrication. In particular, the gallium nitride grown on the aluminum nitride buffer layer may start out growing from the anisotropically etched (111) silicon planes which may be angled towards one another. Eventually, under certain growth conditions, such as higher growth temperatures than may be commonly used, for example temperatures of about 1050° C. to about 1100° C., the gallium nitride growth fronts can coalesce and form one common growth front perpendicular to the silicon substrate, to form a continuous and smooth layer.

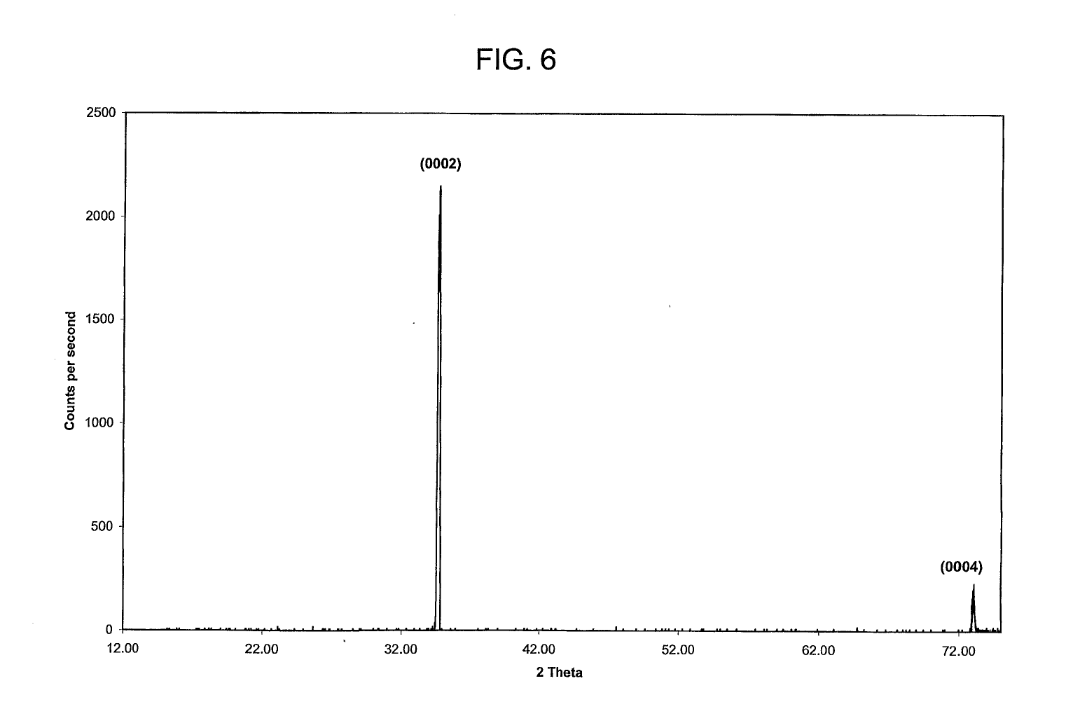

FIG. 6 graphically illustrates X-ray diffraction patterns from a gallium nitride layer 16 that may be formed according to embodiments of the invention that were described in connection with FIGS. 1-2. This X-ray diffraction pattern shows a large, narrow peak at 34.6°. This large, narrow peak, and the absence of other peaks, indicates that a high quality 2H-gallium nitride layer has been formed.

In the drawings and specification, there have been disclosed typical preferred embodiments of the invention and, although specific terms are employed, they are used in a generic and descriptive sense only and not for purposes of limitation, the scope of the invention being set forth in the following claims.

What is claimed is:

1. A method of fabricating a gallium nitride semiconductor layer comprising:
exposing (111) crystallographic planes in a face of a (100) silicon substrate; and
growing hexagonal gallium nitride on the (111) crystallographic planes that are exposed.

2. A method according to claim 1 wherein the exposing comprises wet etching the face of the (100) silicon substrate to expose the (111) crystallographic planes therein.

3. A method according to claim 2 wherein the wet etching comprises wet etching the face of the (100) silicon substrate in KOH to expose the (111) crystallographic planes therein.

4. A method according to claim 1 wherein the exposing comprises:
selectively masking the face of the (100) silicon substrate; and
selectively etching the face of the (100) silicon substrate that is selectively masked to thereby expose the (111) crystallographic planes in the face of a (100) silicon substrate.

5. A method according to claim 1 wherein the exposing comprises:
exposing randomly spaced apart (111) crystallographic planes in the face of the (100) silicon substrate.

6. A method according to claim 1 wherein the following is performed between the exposing and growing:
forming a buffer layer comprising aluminum nitride on the (111) crystallographic planes that are exposed in the face of the (100) silicon substrate; and
wherein the growing comprises growing hexagonal gallium nitride on the buffer layer comprising aluminum nitride opposite the (111) crystallographic planes.

7. A method according to claim 6:
wherein the forming comprises forming a buffer layer comprising aluminum nitride on the face of the (100) silicon substrate including on the (111) crystallographic planes that are exposed; and
wherein the growing comprises growing hexagonal gallium nitride on buffer layer comprising aluminum nitride, including opposite the (111) crystallographic planes.

8. A method according to claim 6:
wherein the forming a buffer layer comprises forming a buffer layer comprising a first layer comprising silicon carbide on the (111) crystallographic planes that are exposed in the face of the (100) silicon substrate, and a second layer comprising aluminum nitride on the first layer comprising silicon carbide; and
wherein the growing comprises growing hexagonal gallium nitride on the second layer comprising aluminum nitride, opposite the first layer comprising silicon carbide.

9. A method according to claim 1 wherein the growing comprises growing hexagonal gallium nitride on the (111) crystallographic planes until the hexagonal gallium nitride coalesces to form a continuous hexagonal gallium nitride layer.

10. A method according to claim 9 wherein the growing is followed by forming at least one microelectronic device in the continuous hexagonal gallium nitride layer.

11. A method according to claim 1 wherein the growing is followed by forming at least one microelectronic device in the hexagonal gallium nitride.

12. A method according to claim 1 wherein the (100) silicon substrate is a bulk (100) silicon substrate or a (100) silicon layer on a silicon or nonsilicon substrate.

13. A method of fabricating a gallium nitride semiconductor layer comprising:
texturing a face of a (100) silicon substrate; and
growing hexagonal gallium nitride on the face of the (100) silicon substrate that is textured.

14. A method according to claim 13 wherein the texturing comprises wet etching the face of the (100) silicon substrate.

15. A method according to claim 14 wherein the wet etching comprises wet etching the face of the (100) silicon substrate in KOH.

16. A method according to claim 13 wherein the texturizing comprises:
selectively masking the face of the (100) silicon substrate; and
selectively etching the face of the (100) silicon substrate that is selectively masked.

17. A method according to claim 13 wherein the following is performed between the texturizing and growing:
forming a buffer layer comprising aluminum nitride on the face of the (100) silicon substrate that is textured; and
wherein the growing comprises growing hexagonal gallium nitride on buffer layer comprising aluminum nitride opposite the face of the (100) silicon substrate that is textured.

18. A method according to claim 17:
wherein the forming a buffer layer comprises forming a buffer layer comprising a first layer comprising silicon carbide on the face of the (100) silicon substrate that is textured, and a second layer comprising aluminum nitride on the first layer comprising silicon carbide; and
wherein the growing comprises growing hexagonal gallium nitride on the second layer comprising aluminum nitride, opposite the first layer comprising silicon carbide.

19. A method according to claim 13 wherein the growing comprises growing hexagonal gallium nitride on the face of the (100) silicon substrate that is textured until the hexagonal gallium nitride coalesces to form a continuous hexagonal gallium nitride layer.

20. A method according to claim 19 wherein the growing is followed by forming at least one microelectronic device in the continuous hexagonal gallium nitride layer.

21. A method according to claim 13 wherein the growing is followed by forming at least one microelectronic device in the hexagonal gallium nitride.

22. A method according to claim 13 wherein the (100) silicon substrate is a bulk (100) silicon substrate or a (100) silicon layer on a silicon or nonsilicon substrate.

23. A method of fabricating a gallium nitride semiconductor layer comprising:
dipping a face of a (100) silicon substrate in KOH; and
growing hexagonal gallium nitride on the face of the (100) silicon substrate that is dipped in KOH.

24. A method according to claim 23 wherein the dipping comprises:
selectively masking the face of the (100) silicon substrate; and
dipping the face of the (100) silicon substrate that is selectively masked in KOH.

25. A method according to claim 23 wherein the following is performed between the dipping and growing:
forming a buffer layer comprising aluminum nitride on the face of the (100) silicon substrate that is dipped in KOH; and
wherein the growing comprises growing hexagonal gallium nitride on buffer layer comprising aluminum nitride opposite the face of the (100) silicon substrate that is dipped in KOH.

26. A method according to claim 25:
wherein the forming a buffer layer comprises forming a buffer layer comprising a first layer comprising silicon carbide on the face of the (100) silicon substrate that is dipped in KOH, and a second layer comprising aluminum nitride on the first layer comprising silicon carbide; and
wherein the growing comprises growing hexagonal gallium nitride on the second layer comprising aluminum nitride, opposite the first layer comprising silicon carbide.

27. A method according to claim 23 wherein the growing comprises growing hexagonal gallium nitride on the face of the (100) silicon substrate that is dipped in KOH until the hexagonal gallium nitride coalesces to form a continuous hexagonal gallium nitride layer.

28. A method according to claim 27 wherein the growing is followed by forming at least one microelectronic device in the continuous hexagonal gallium nitride layer.

29. A method according to claim 23 wherein the growing is followed by forming at least one microelectronic device in the hexagonal gallium nitride.

30. A method according to claim 23 wherein the (100) silicon substrate is a bulk (100) silicon substrate or a (100) silicon layer on a silicon or nonsilicon substrate.

31. A gallium nitride semiconductor structure comprising:
a (100) silicon substrate including exposed (11) crystallographic planes in a face thereof, and
a layer comprising hexagonal gallium nitride on the (111) crystallographic planes.

32. A structure according to claim 31 wherein the exposed (111) crystallographic planes comprise a plurality of regularly spaced apart exposed (111) crystallographic planes.

33. A structure according to claim 31 wherein the exposed (111) crystallographic planes comprise a plurality of randomly spaced apart exposed (111) crystallographic planes.

34. A structure according to claim 31 further comprising:
a layer comprising aluminum nitride between the (111) crystallographic planes that are exposed in the face of the (100) silicon substrate and the layer comprising hexagonal gallium nitride.

35. A structure according to claim 34 further comprising:
a layer comprising silicon carbide between the layer comprising aluminum nitride and the (111) crystallographic planes that are exposed.

36. A structure according to claim 31 wherein the layer comprising hexagonal gallium nitride layer comprises a continuous layer comprising hexagonal gallium nitride on the (111) crystallographic planes.

37. A structure according to claim 36 further comprising at least one microelectronic device in the continuous layer comprising hexagonal gallium nitride.

38. A structure according to claim 31 further comprising at least one microelectronic device in the continuous layer comprising hexagonal gallium nitride.

39. A structure according to claim 31 wherein the (100) silicon substrate is a bulk (100) silicon substrate or a (100) silicon layer on a silicon or nonsilicon substrate.

40. A gallium nitride semiconductor structure comprising:
a (100) silicon substrate including a textured face; and
a layer comprising hexagonal gallium nitride on the textured face.

41. A structure according to claim 40 wherein the textured face comprises a periodically textured face.

42. A structure according to claim 40 wherein the textured face comprises a randomly textured face.

43. A structure according to claim 40 further comprising:
a buffer layer comprising aluminum nitride between the textured face of the (100) silicon substrate and the layer comprising hexagonal gallium nitride.

44. A structure according to claim 43 further comprising:
a layer comprising silicon carbide between the layer comprising aluminum nitride and the textured face.

45. A structure according to claim 40 wherein the layer comprising hexagonal gallium nitride comprises a continuous layer comprising hexagonal gallium nitride on the textured face.

46. A structure according to claim 45 further comprising at least one microelectronic device in the layer comprising continuous hexagonal gallium nitride.

47. A structure according to claim 40 further comprising at least one microelectronic device in the layer comprising hexagonal gallium nitride.

48. A structure according to claim 40 wherein the (100) silicon substrate is a bulk (100) silicon substrate or a (100) silicon layer on a silicon or nonsilicon substrate.
